(19) United States
(12) Patent Application Publication
(10) Pub. No.: US 2003/0075671 A1
(43) Pub. Date: Apr. 24, 2003

(54) Method and apparatus for reducing power saturation in photodetectors

(76) Inventor: Yet-Zen Liu, Westlake Village, CA (US)

Correspondence Address: BROBECK, PHLEGER & HARRISON LLP, 12390 EL CAMINO REAL, SAN DIEGO, CA, 92130, US

(21) Appl. No.: 10/027,605

(22) Filed: Oct. 19, 2001

(51) Int. Cl. H01L 31/00

(52) U.S. Cl. 250/214.1

(57) ABSTRACT

A method and apparatus for reducing power saturation in a photodetector is provided. The photodetector includes a plurality of parallel absorption channels that receive and split incident light into plural segments. The parallel absorption channels operate as multi mode interference couplers.

### BACKGROUND OF THE INVENTION

1. Field of the Invention

The present invention relates to devices and methods used in fiber optics networks and more particularly, to semiconductor photodetectors.

2. Background

Conventional waveguide type, photodetectors (hereinafter referred as “photodetector” or “photodetectors”) are used extensively in fiber optics networks. FIG. 1A shows a top level block diagram of a typical fiber optics network 100, which includes a transmitter 100A that receives an electrical input (not shown) and converts it to an optical output 100B using a laser diode (not shown). Optical signal 100B is transmitted via fiber (not shown) and is received by optical amplifier 100C. Optical amplifier 100C amplifies optical signal 100B and the amplified signal 100D is transmitted to photodetector 100F, via filter 100E.

Conventional photodetectors utilize a waveguide for guiding incident light to an absorption layer located between p and n-type semiconductor layers. FIGS. 1B and 1C, described below, show a cross-sectional and perspective view, respectively, of a typical waveguide photodetector.

Turning in detail to FIG. 1B, a laminated structure is sequentially formed by a n-type cladding layer 104, an absorption layer 103, a p-type cladding layer 102 and an ohmic contact layer 101, on a semiconductor substrate 105. Electrodes (not shown) are mounted on ohmic contact layer 101 and on the back surface of layer 105. If a reverse voltage is applied between layer 102 and layer 104, incident light (not shown) guided to absorption layer 103 is converted into a photoelectric signal because electric field is maintained within a depletion layer created within absorption layer 103. Excited carriers within the depletion layer are detected as photoelectric current.

Turning in detail to FIG. 1C, is a perspective view of a conventional photodetector 106 with a cut-out cross-sectional view showing absorption layer 103 between layers 102 and 104. In photodetector 106, the total optical power generated by absorbed incident light is exponentially dependent upon the distance that incident light has to travel in absorption layer 103. Typically, most of the incident light (not shown, perpendicular to the paper surface of FIG. 1C) is absorbed in the front area 103A of absorption layer 103. High concentration of absorbed photons result in high density of generated current carriers, resulting in reduced efficiency and power saturation of photodetector 106.

One common solution to the foregoing problem is to reduce the confinement factor for the waveguide design, by reducing absorption layer 103's thickness (“T”, as shown in FIG. 1C) with respect to the overall waveguide thickness (“T1”, as shown in FIG. 1C), and hence reducing the effective absorption coefficient. However, to offset the reduction in thickness, the length l (FIG. 1C) of the photodetector must be increased to absorb the same amount of incident light, which will result in higher capacitance due to increase in the waveguide sectional area, which ultimately reduces the overall photodetector efficiency. Furthermore, in a longer photodetector the velocity mismatch between optical and electric waves will produce noise in the detected optical signal.

Therefore, there is a need to reduce power saturation in a photodetector without increasing the overall length of the photodetector.

### SUMMARY OF THE INVENTION

There is provided in accordance with one aspect of the present invention a method and apparatus to reduce power saturation in a photodetector without increasing the photodetector length. The present invention provides a photodetector with plural parallel absorption channels (N) that split incident light received from optical fiber into N segments. Because the absorption channels are parallel to each other, the overall length of the photodetector is not increased to absorb more incident light.

In accordance with another aspect of the present invention, there is provided a method and apparatus wherein the photodetector efficiency is improved without increasing channel length or capacitance. Furthermore, since absorption channels are connected in parallel, the overall series resistance is reduced by a factor of N (number of plural absorption channels).

This brief summary has been provided so that the nature of the invention may be understood quickly. A more complete understanding of the invention can be obtained by reference to the following detailed description of the preferred embodiments thereof in connection with the attached drawings.

### BRIEF DESCRIPTION OF THE DRAWINGS

FIG. 1A, as described above, is a block diagram of a conventional fiber optics network.

FIG. 1B, as described above, is a cross-sectional view of a conventional photodetector.

FIG. 1C, as described above, is a perspective view of a conventional photodetector.

FIG. 2 illustrates a top view of a photodetector with parallel absorption channels, according to an embodiment of the present invention.

FIG. 3 illustrates a process flow diagram for a photodetector using parallel absorption channels, according to an embodiment of the present invention.

Features appearing in multiple figures with the same reference numeral are the same unless otherwise indicated.

### DETAILED DESCRIPTION

In one aspect of the present invention, plural parallel absorption channels are provided such that incident light that enters the optical path of a photodetector is absorbed by those plural parallel absorption channels. Because plural parallel absorption channels are used, the overall length of the photodetector is not increased which does not increase the overall capacitance of the photodetector.

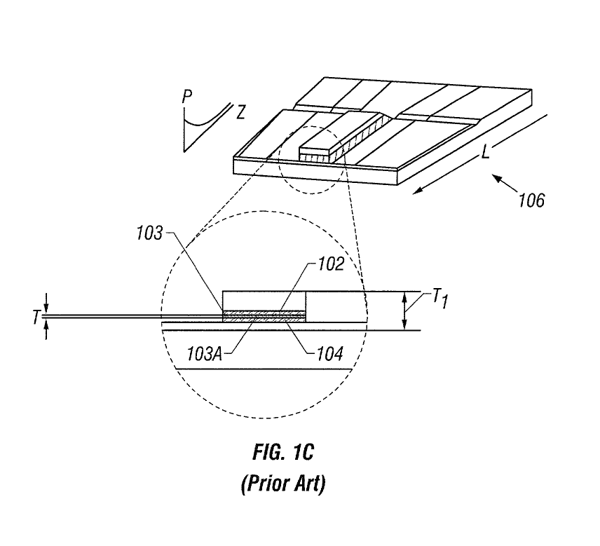

Turning in detail to FIG. 2, is waveguide 200 of a photodetector (not shown) with incident light 201 entering optical path 202. Incident light 201 is absorbed by N parallel absorption channels 203 of a multi mode interference coupler 203A that utilize properties of multi mode interference couplers (“MMI”) to split incident light 201 into N segments, and thereafter absorb incident light 201. Since incident light 201 is split into N segments its power density is reduced by a factor of N, which reduces power saturation of the photodetector. Power density is defined as optical power, P, within the waveguide cross-section, divided by the waveguide cross-sectional area.

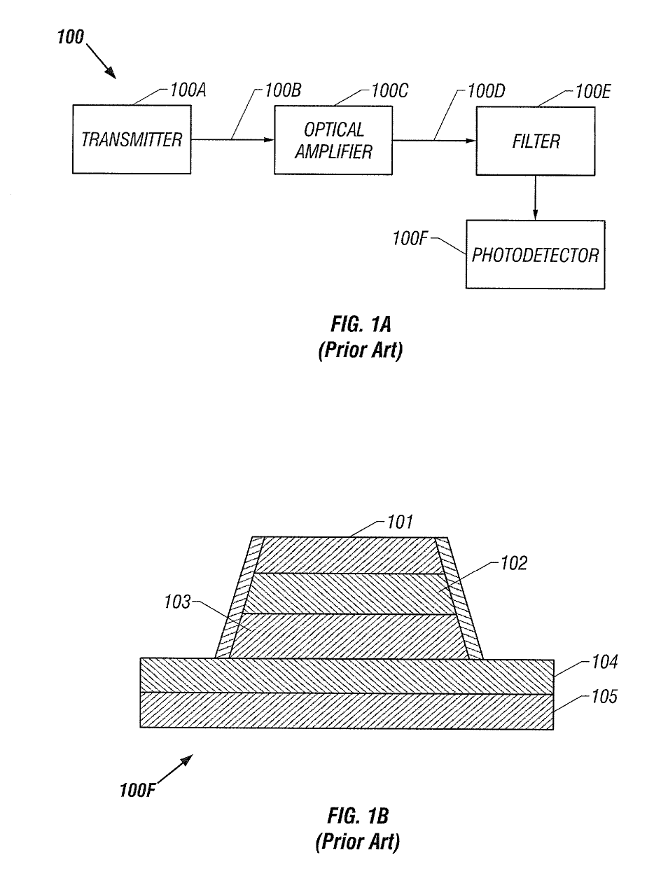

In another aspect of the present invention, the length of the plural absorption channels of waveguide 200 is chosen such that the junction capacitance of waveguide 200 and 106 [FIG. 1B] is substantially similar. The length l of waveguide 106 is given by: 2(Γ₀α)-¹ where Γ₀α is the effective absorption coefficient of the waveguide channel and Γ₀ is the confinement factor of the waveguide. To maintain the junction capacitance for waveguide 200, substantially similar to that of the single channel waveguide 106 with length l, the length L 204 for N parallel absorption channels 203 is given by:

L=l/N

The foregoing relationship maintains the same capacitance as that of a series channel absorber shown in FIG. 1B, with length l and absorbs more incident light without increasing the overall channel length.

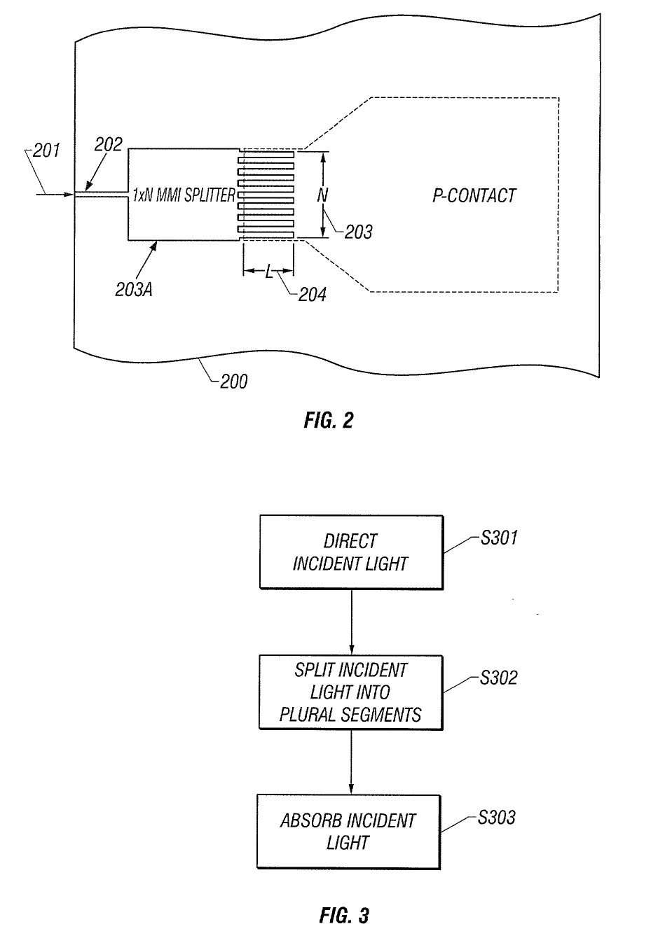

In yet another aspect of the invention, referring to FIG. 3, a process is provided such that incident light that enters the optical path leading to a photodetector waveguide is absorbed by plural parallel absorption channels. Because plural parallel absorption channels are used, the overall capacitance of the photodetector is not increased, while the plural parallel absorption channels compared to photodetectors with a single absorption channel absorb more light.

The process flow diagram of FIG. 3 comprises of: directing incident light to N absorption channels; splitting the incident light into N segments, wherein the light is split by plural parallel absorption channels operating as MMI couplers; and absorbing the split incident light.

Turning in detail to FIG. 3, in Step S301, incident light is directed to N parallel absorption channels 203 [FIG. 2]. Incident light 201 enters optical path 202.

In Step S302, incident light 201 is split into plural segments. N absorption channels 203 operate as MMI couplers, as described above, and split incident light 201 into N segments.

In step S303, incident light that is split into N segments is absorbed by N absorption channels 203.

In yet another aspect of the present invention the photodetector efficiency is improved without increasing channel length or increasing capacitance.

In another aspect of the present invention, the overall series resistance is reduced by a factor of N since absorption channels are all connected in parallel,

While the present invention is described above with respect to what is currently consider its preferred embodiments, it is to be understood that the invention is not limited to that described above. To the contrary, the invention is intended to cover various modifications and equivalent arrangements within the spirit and scope of the appended claims.

What is claimed is:

1. A photodetector, comprising:
a plurality of parallel absorption channels for receiving incident light, wherein the plural channels split the incident light.

2. The apparatus of claim 1, wherein the length of the plural parallel absorption channels is less than the length of a single channel photodetector with substantially the same junction capacitance as that of the photodetector with the parallel channels.

3. The photodetector of claim 1, wherein the parallel absorption channels operate as multi mode interference couplers.

4. A method for reducing power saturation in a photodetector, comprising:
absorbing incident light, wherein the incident light is absorbed by a plurality of parallel absorption channels.

5. The method of claim 4, wherein the length of the plural parallel absorption channels is less than the length of a photodetector with a single absorption channel with substantially the same junction capacitance as the photodetector with plural parallel absorption channels.

6. The method of claim 4, wherein the plural absorption channels operate as multi mode interference couplers.

7. An apparatus for reducing power saturation in a photodetector, comprising:
means for splitting incident light wherein the incident light is split by a plurality of parallel absorption channels.

8. The apparatus of claim 7, wherein the length of the plural parallel absorption channels is less than the length of a photodetector with a single channel with substantially the same junction capacitance as that of the photodetector with the parallel channels.

9. The apparatus of claim 7, wherein the plural parallel absorption channels operate as multi mode interference couplers.

10. A system for reducing power saturation in a photodetector, comprising:
a plurality of parallel absorption channels, wherein the plural absorption channel receive incoming incident light.

11. The system of Method 10, wherein the plural absorption channels operate as multi-mode interference couplers.
